(19) United States
(12) Patent Application Publication
(10) Pub. No.: US 2007/0030657 A1
(43) Pub. Date: Feb. 8, 2007

(54) Circuit board with a cooling architecture

(75) Inventor: Nobuaki Hanai, Tokyo (JP)

Correspondence Address: Paul D. Greeley;Ohlandt, Greeley, Ruggiero & Perle, L.L.P., 10th Floor, One Landmark Square, Stamford, CT, 06901-2682, US

(73) Assignee: Agilent Technologies, Inc.

(21) Appl. No.: 11/436,754

(22) Filed: May 18, 2006

(30) Foreign Application Priority Data
Aug. 4, 2005 (JP) 2005-226195

(51) Int. Cl. H05K 7/20

(52) U.S. Cl. 361/721; 361/700

(57) ABSTRACT

A circuit board with a heatsink comprising a first circuit board wherein the electronic components are disposed on both surfaces; a pipe disposed in a predetermined pattern on the front surface side of the first circuit board; and a heat-conducting block disposed around the periphery of the pipe, characterized in that multiple through-holes are disposed along the pattern of the first circuit board and part of the block is exposed to the back surface side of the first circuit board by means of the through-holes.

### 1. FIELD OF THE INVENTION

The present invention relates to a circuit board with a heatsink and in particular, to a circuit board having a heatsink that uses a liquid cooling medium.

### 2. DISCUSSION OF THE BACKGROUND ART

Forced-air cooling systems that use an air cooling fan have often been used in the past as means for preventing a buildup of excess heat in electronic circuits. Nevertheless, due to the high-density-mounted circuit boards used in numerous electronic calculators and measurement devices and the like, heat-generating components such as ICs and LSIs are mounted to high density and there is a tendency toward a considerable increase in the quantity of heat generated; however, systems that use air cooling fans have a limited cooling capacity. Moreover, the space for mounting a heat-radiating or heat-dissipating unit inside the board has gradually become smaller as a result of the rapid progress made in the miniaturization of circuit boards and it is now very difficult to dissipate the heat that is generated on the circuit board.

In order to solve such problems, a heatsink mechanism has been proposed and partially put to practical use, wherein a heat conductor is used to take up the heat generated via electronic components and dissipate this heat from these electronic components. By means of such a proposal, a heat-conducting block, or similar means is brought into contact with the electronic components, particularly those that must be cooled, and an excessive increase in temperature of these electronic components is prevented through the transfer of this heat to the heat-conducting block or similar means. Furthermore, in order to more efficiently emit the heat that has been transmitted to the block or similar means to outside the circuit board, a liquid-cooling heatsink such as described in JP Unexamined Patent Specification (Kokai) 2002-81874 has been proposed with which heat-dissipating efficiency is improved by disposing a pipe-shaped path in the heat-conducting block and circulating a cooling medium in this path.

Nevertheless, as a result of the recent miniaturization of electronic devices, there has been an increase in recent years in double surface-mounted circuit boards wherein electronic components are disposed on both surfaces of a circuit board, as well as layered circuit boards wherein sub-boards are fastened to the top of a base board. Heat-generating components are mounted on both surfaces of the board with a double surface-mounted board; therefore, a cooling mechanism having heat-dissipating effects on both surfaces of the board is necessary. Moreover, a layered circuit board requires a cooling mechanism that has a heat-dissipating effect on each layer. The method whereby a heatsink is disposed on both surfaces of a double surface-mounted circuit board, or for each layer of a layered circuit board will be considered as the simplest cooling mechanism that accomplishes this purpose.

However, liquid cooling-type heatsinks require that a path be disposed in the heatsink; therefore, the heatsink must have the corresponding thickness. As a result, even if the board itself is miniature as a result of having a double surface-mounted structure or layered structure, it may have several heatsinks for cooling of the substrate and this in turn increases the size of the board. In particular, large electronic devices and measuring instruments often have a system architecture wherein the circuit board is inserted in multiple bus slots disposed in rows at equal intervals, and in such cases each board must be thinner then the intervals between the slots. Therefore, there is a demand for double surface-mounted circuit boards and layered circuit boards with heatsinks that are miniature and have sufficient cooling capability.

Moreover, in the case of a cooling mechanism wherein two plates are overlapped in order to form a path for a cooling medium as in Patent Reference 1, it is necessary to use relatively thick plates and to perform leak-proof finishing of joints in order to prevent leakage of the cooling medium. Therefore, there are problems in that there are limits to the thinness of the heatsink, and because the structure is complex, finishing is difficult. Therefore, there is a need for a circuit board with a heatsink attached having a structure that is simple, yet capable of preventing leakage of cooling medium.

### SUMMARY OF THE INVENTION

The above-mentioned problems are solved by a circuit board with a heatsink comprising a first circuit board with electronic components disposed on both surfaces; a pipe arranged in a predetermined pattern on the front surface side of the first circuit board; and a heat-conducting block disposed around the periphery of the pipe, characterized in that the first circuit board has multiple through-holes disposed along the pattern, and part of the block is exposed via the through-holes to the back surface side of the first circuit board.

That is, it is possible to prevent leakage of cooling medium with a simple structure by using a pipe to form a path for the cooling medium. Moreover, the heat-dissipating capability can be improved by disposing a heat-conducting block along this pipe, because the heat transfer efficiency to the pipe from electronic components that generate large quantities of heat is improved. Furthermore, it is possible to cool electronic components mounted on both surfaces of the board while preventing leakage of cooling medium by exposing the heat-conducting block to the back surface of the circuit board via through-holes made in the circuit board. It should be noted that when sub-boards are disposed on the front surface or the back surface of the double surface-mounted substrate, each of the circuit boards that form the layered structure can be more efficiently cooled by joining the heat-generating components on the sub-board in question and the heatsink such that they are in a state of thermal conduction by direct contact or via a heat-conducting block.

It is possible to provide a miniature, thin circuit board with a liquid cooling-type heatsink.

### BRIEF DESCRIPTION OF THE DRAWINGS

FIG. 1 is an oblique view from the top of the circuit board described by the working example of the present invention.

FIG. 2 is a detailed drawing showing the circuit board of FIG. 1 by its structural parts.

FIG. 3 is an oblique view showing the circuit board of FIG. 1 from the base.

FIG. 4 is an enlarged oblique view of the heatsink described with the working example of the present invention.

FIG. 5 is a cross section of part of the circuit board described with the working example of the present invention.

### DETAILED DESCRIPTION OF THE PREFERRED EMBODIMENT

Representative working examples of the present invention will now be described while referring to the drawings.

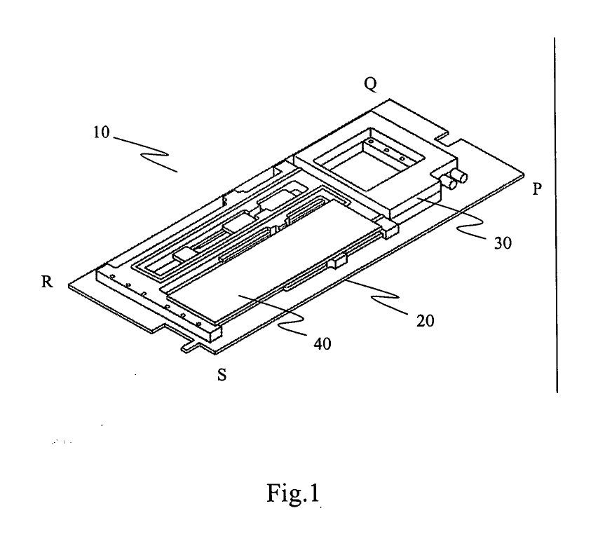

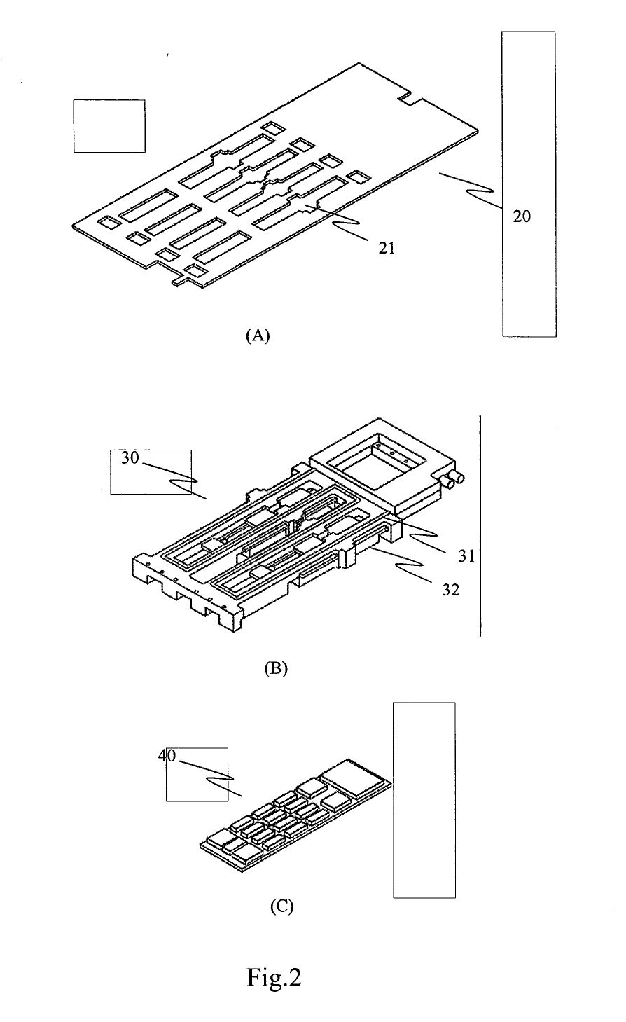

FIG. 1 is an oblique view from the top surface of a circuit board 10 with a heatsink of the present invention. Moreover, FIG. 2 is a detailed drawing showing a circuit board with a heatsink by each of its structural parts.

Circuit board 10 with a heatsink comprises a base board 20 wherein components are mounted on both surfaces (FIG. 2(A)); a heatsink 30 having a pipe 31 through which cooling medium flows and a heat-conducting block 32 (FIG. 2 (B)); and a sub-board 40 disposed over base board 20 with a space in between the boards. It should be noted that the electronic components on base board 20 are omitted in order to more easily study the drawing.

Pipe 31 is made from aluminum metal and has been bent to a predetermined pattern that forms a path for the circulation of cooling medium. By means of circuit board 10 of the present working example, sub-board 40 is positioned from the center of the surface of base board 20 toward the front in the drawing, as shown in FIG. 1. Another identical sub-board (not illustrated) as this sub-board 40 is in a position of linear symmetry with sub-board 40 with respect to the center in the direction of length. Two sub-boards 40 are similarly disposed on the back surface. One of these sub-boards is drawn in FIG. 2(C). Pipe 31 is disposed along two sides, from the right front (toward point P) of base board 20 through the back right (toward point Q) to the back left point (toward point R), as shown in FIG. 1. The pipe is further laid back and forth between the left side (point R to point S) to the center, from the back left (toward point R) to the front left (toward point S) to form a pattern from the front left (toward point S) to the right front (point P). Thus, sub-board 40 is disposed where pipe 31 has been laid in a back-and-forth pattern. It should be noted that the above-mentioned pattern is one example and the pattern can be designed as needed based on the position of the heat-generating components. Moreover, the pipe is not necessarily aluminum and can be any material that has a high heat conductivity, such as SUS or copper.

The cooling medium path formed by heatsink 30 of the present example is a pipe-shaped member and therefore, there is virtually no problem with leakage of liquid. Moreover, pipe 31 can be disposed in a two-dimensional pattern along the front surface side of the base board; therefore, forming of the pipe is facilitated, and because fluid resistance is low, the cooling medium circulating device for introducing and discharging cooling medium (not illustrated) puts little outside stress on circuit board 10. Although water is used as the cooling medium in circuit board 10 of the present working example, liquid nitrogen, HCFC (hydrochlorofluorocarbons), or another cooling medium can also be used.

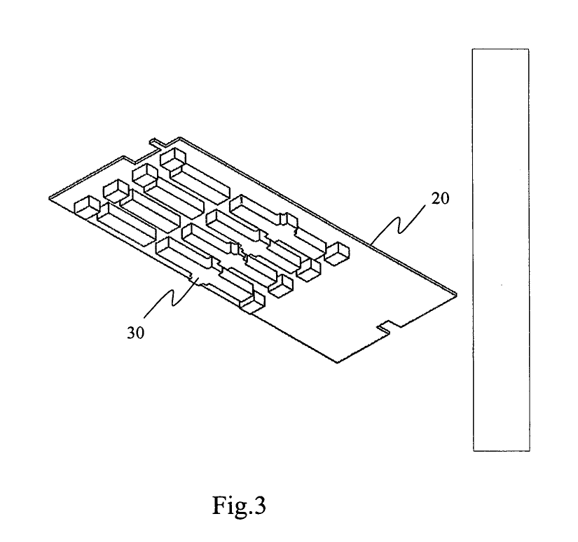

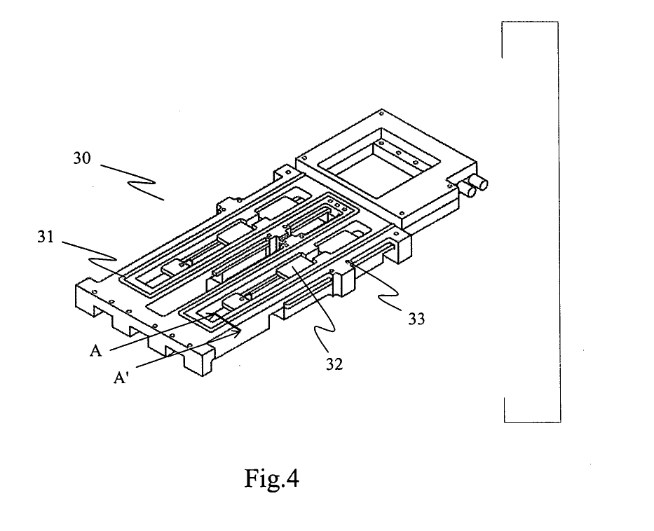

As shown in FIG. 4, a heat-conducting block 32 made of aluminum metal is disposed around the periphery of pipe 31 and is responsible for heat transfer from the components that generate a particularly large quantity of heat (not illustrated) to pipe 31. The material used for heat-conducting block 32 is not limited to aluminum and can be any material of high thermal conductivity, such as gold, silver, copper, or iron. Heat-conducting block 32 is disposed as shown in FIG. 3 such that it is exposed to the back surface side of base board 20 via through-holes 21 in base board 20. As a result, it is possible to use one heatsink 30 to cool each of sub-boards 40 that are disposed over the two surfaces of base board 20 with a space in between each of the sub-boards and the front and back surfaces of base board 20.

In this case, it is not necessary to dispose through-holes 21 over the entire pipe 31; the through-holes can be disposed such that heat conducting block 32 is exposed close to those parts that generate large quantities of heat and are disposed on the back surface of base board 20 and sub-board 40 on the back surface side. Exposed heat-conducting block 32 and the components on the back surface of base board 20 can be joined by a component of high heat conductivity, such as a heat-conducting film or metal. However, unless the components generate a very large quantity of heat, a particularly heat-conductive member is not necessary and the corresponding dissipating effect can be realized by simply cooling the air around the components using the cooling medium flowing through pipe 31. Thus, the strength of the base board can be retained by disposing through-holes 21 only where they are necessary.

Fastening holes 33 for sub-board 40 are made in heat-conducting block 32. As a result, heat-conducting block 32 serves not only as a heat-dissipating means but also as a fastening member for a fastening sub-board 40 to base board 10. The heat-conducting efficiency between sub-board 40 and heat-conducting block 32 is improved, and the heat generated at sub-board 40 can be more efficiently dissipated by directly fastening sub-board 40 to heat-conducting block 32.

Sub-board 40 is also a double surface-mounted board, but the electronic components that generate large quantities of heat are disposed primarily on one surface. Therefore, when sub-board 40 is fastened to fastening hole 33 of heatsink 30, it is fastened by being screwed in place such that the surface having the electronic components that generate large quantities of heat faces toward the side of heatsink 30. As shown in FIGS. 1 and 2, pipe 31 in the present working example forms a pattern such that it wraps around the periphery along three sides of sub-board 40. In addition, heat-conducting block 32 is disposed such that it directly contacts the electronic components that generate large quantities of heat. As a result, heatsink 10 can provide high heat-dissipating capability, not only for base board 20, but also for sub-board 40.

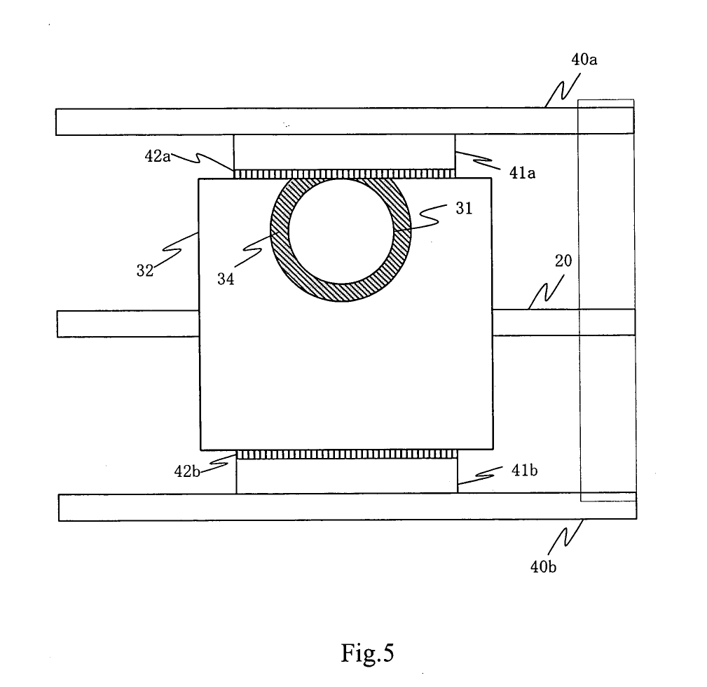

Finally, the structure of the joints between pipe 31 and heat-conducting block 32 will be described while referring to the cross-section in FIG. 5. FIG. 5 is a cross-section along A-A′ in FIG. 4 of circuit board 10, wherein base board 20 and sub-boards 40a and 40b are fastened to heatsink 30.

Pipe 31 is buried in heat conducting block 32. This pipe 31 is formed by inserting a pipe with a smaller diameter than in the finished state in a groove in the top of heat-conducting block 32 and then expanding the pipe by increasing the inner pressure. The diameter of pipe 31 after it has been expanded is greater than the width of the opening at the top surface of the heat-conducting block; therefore, pipe 31 will not come loose from heat-conducting block 32. A heat-conducting adhesive 34 in which silver powder has been mixed is filled in between pipe 31 and heat conducting block 32 in order to maintain heat conductivity. Any adhesive material can be used for binder 34 as long as it has a high heat conductivity and it can withstand the high temperature that is applied when the pipe is expanded.

However, pipe 31 is not disposed in the center of heat-conducting block 32 but is instead disposed toward the front surface side of base board 20. Taking into consideration the uniform radiation of heat over both surfaces of the board, it is preferred that pipe 31 is disposed in the center of heat-conducting block 32. Nevertheless, if the pipe is disposed toward the center and is designed so that it wraps around the periphery of the same one surface, through-holes must be made in base board 20 over the entire pattern made by pipe 31. In such a case, the surface area for electronic components on base board 20 will be smaller and base board 20 will be divided into an inside and an outside by pipe 31, making necessary a tangent for connecting the signals between the two parts. Therefore, the necessary cooling capacity is realized with circuit board 10 of the present working example by disposing pipe 31 toward the front surface side of base board 20 and forming through-holes 21 only where necessary as in FIG. 3 in order to expose heat-conducting block 32.

A heat-generating component 41a (for instance, a DC-DC converter, regulator, power amplifier, and the like) attached on sub-board 40a is joined directly to the top surface of heat-conducting block 32 (front surface side of base board 20). A silicone heat-conducting grease 42a is applied to the joining surfaces in order to improve heat conductivity. Similarly, a heat-generating component 41b fastened on sub-board 40b is joined directly to the bottom surface of heat-conducting block 32 (back surface side of base board 20), and a heat-conducting grease 42b is applied to the joining surfaces. Heat conducting greases 42a and 42b are not necessarily silicone and can be another grease, such as a grease mixed with a metal oxide or carbon powder; a heat-conducting member in sheet form, such as metal foil; a gap filler; and the like.

Heat-conducting block 32 is designed such that it projects to the same height on the front surface side and the back surface side of base board 20. Therefore, the distance between base board 20 and sub-board 40a is the same as the distance between base board 20 and sub-board 40b. By forming heat-conducting block 32 and sub-boards 40a and 40b such that the surfaces thereof are symmetrical with respect to base board 20, it is possible to provide the same distribution of cooling properties at the front surface side and at the back surface side.

The present description used the phrases “front surface” and “back surface” as they relate to base board 20 and “top surface” and “bottom surface” as they relate to the heat-conducting block, but these phrases merely facilitated the understanding of the description using the drawings and there is no technical or structural significance to differentiating between the front and back and top and bottom, in particular. Consequently, even if front and back and top and bottom are used interchangeably, the technical significance of the present invention will be the same. The technical concept of the present invention has been described in detail while referring to specific working examples, but it is obvious that the present invention can undergo various modifications and revisions by persons skilled in the art of the present invention without deviating from the substance or scope of the claims.

What is claimed is:

1. A circuit board with a heatsink comprising:
a first circuit board with electronic components disposed on both surfaces;
a pipe arranged in a predetermined pattern on the front surface side of the first circuit board; and
a heat-conducting block disposed around the periphery of the pipe,
wherein the first circuit board has multiple through-holes disposed along the pattern, and part of the block is exposed via the through-holes to the back surface side of the first circuit board.

2. The circuit board with a heatsink according to claim 1, further comprising:
a second circuit board disposed over one surface or both surfaces of the first circuit board with a space in between the first and second circuit boards,
wherein the second circuit board is disposed such that some of the electronic components on the second circuit board are in a thermally conductive state with the block.

3. The circuit board with a heatsink according to claim 2, wherein said second circuit board is disposed over both surfaces of the first circuit board such that the distance from the first circuit board to the second circuit board is the same on both surfaces.

4. The circuit board with a heatsink according to claim 2, wherein a predetermined pattern is formed such that it wraps around the periphery of the board of the second circuit board.

5. The circuit board with a heatsink according to claim 2, wherein said heat-conducting block is an attachment member of the second circuit board.

6. The circuit board with a heatsink according to claim 1, wherein said through-holes are near the components that generate large quantities of heat.
